(19) United States
(12) Patent Application Publication
(10) Pub. No.: US 2025/0029671 A1
(43) Pub. Date: Jan. 23, 2025

(54) INTEGRATED RANDOM ACCESS MEMORY USING INVERTER LOOPS

(71) Applicant: Taalas Inc., Toronto (CA)

(72) Inventor: Ljubisa Bajic, Toronto (CA)

(21) Appl. No.: 18/769,849

(22) Filed: Jul. 11, 2024

Related U.S. Application Data
(60) Provisional application No. 63/527,825, filed on Jul. 20, 2023.
(60) Provisional application No. 63/546,920, filed on Nov. 1, 2023.

(51) Int. Cl. G11C 21/00

(52) U.S. Cl. CPC G11C 21/00

(57) ABSTRACT

Methods and systems which involve computer memories are disclosed herein. The methods and systems involve integrated Random Access Memory (RAM) using loops of inverters. A disclosed RAM comprises a set of loops of inverters. The loops of inverters in the set of loops of inverters are addressable using a set of corresponding addresses. The RAM further comprises a write circuit configured to write a value to a first loop of inverters when provided with a corresponding address for the first loop of inverters. The first loop of inverters is in the set of loops of inverters and the corresponding address is in the set of corresponding addresses. The RAM further comprises a read circuit configured to read the value from the first loop of inverters when provided with the corresponding address.

### CROSS REFERENCE TO RELATED APPLICATIONS

This application claims the benefit of U.S. Provisional Patent Application No. 63,527,825, filed Jul. 20, 2023, and U.S. Provisional Patent Application No. 63/546,920, filed Nov. 1, 2023, both of which are incorporated by reference herein in their entireties for all purposes.

### BACKGROUND

The past years have seen rapid advancements in specialized computing architectures for applications such as cryptography, cloud computing, machine learning, and other applications. While these computing architectures continue to advance in terms of their ability to parallelize complex computations and execute specific computations more efficiently, few advancements have been made with respect to the memory used to store the data structures on which the complex computations are conducted. The lack of fundamental advancements has resulted in a dramatic increase in the relative cost of the memories required for these computing architectures to operate as compared to the cost of the computational components of the architecture. Estimates are that dynamic random access memory (DRAM) is approximately 50% of the cost of most server systems and static random access memory (SRAM) is approximately 50% of the cost of processor chips such as those used for machine learning, general computation, and graphics processing. Accordingly, random access memory (RAM) is approximately 70% of the overall cost of certain computing architectures. As the data structures on which these computing architectures continue to increase in size, this disparity and the relative cost of memory, as compared to the computational components of the architecture, will continue to increase.

DRAM was first invented in 1967 and was described in U.S. Pat. No. 3,387,286. SRAM was first invented in 1963 and was described in U.S. Pat. No. 3,562,721. Since then, there have been major improvements in the performance of DRAM and SRAM as the feature size of the cells has decreased with process improvements. However, relying on process improvements has not allowed memory to scale with improvements in the performance of computational units. This is because improvements in computational units follow a square law with decreases in feature size of transistors according to Moore's Law. Decreases in feature size of transistors lead to decreases in power consumption per switch, increases in speed per switch, and increases in density of the computational units of a computing architecture. In contrast, the same physical laws, when applied to memory cells, only provide a linear benefit in terms of increasing the density of the memory units. This is because power consumption per switch and switching speed do not translate directly to fundamental improvement in the operation of a memory as an element for data storage. The lack of any architectural progress in random access memory for 60 years has led to a great disparity in the performance of memory cells as compared to computational units.

### SUMMARY

Methods and systems which involve computer memories are disclosed herein. The methods and systems involve integrated Random Access Memory (RAM) using loops of inverters. Loops of inverters are chains of inverters arranged so that the output of the last inverter in the chain is connected to the input of the first inverter in the chain. As such, a pulse traveling through the chain can continuously loop through the chain. As the term is used herein, when a pulse is continually looping through the chain, the loop of inverters can be described as oscillating. An example of a loop of inverters is a ring oscillator. Ring oscillators are used as functional units in certain circuits such as in phase locked loops and charge pumps. In specific embodiments of the invention disclosed herein, the loops of inverters disclosed herein can store information in the form of the oscillation states of the loops of inverters. The oscillation states of the loops of inverters can be associated with values such that a loop of inverters having a given oscillation state stores the value associated with that oscillation state.

The loops of inverters disclosed herein can be used as RAM in that the loops of inverters can be independently addressed such that the values stored by the loops of inverters can be independently written by a write circuit and read using a read circuit. As such, each loop of inverters can be considered as a memory cell in standard RAM. The loops of inverters can be arranged in an array in which the various loops of inverters store different values that can be accessed or changed randomly in the array using an address for that specific loop of inverters.

Those of ordinary skill in the art of computer memories will recognize that addressing schemes for RAMs can include both explicit addressing of individual memory cells and inherent addressing of an individual memory cell based on an explicit address combined with an order in which, or the signal line from which, the value is read from or written to the memory. As used herein both explicit and inherent addressing of bits are included within the definition of being independently addressed.

Those of ordinary skill in the art of computer memories will also recognize that a read circuit and a write circuit can be provided with different physical signals to address the same memory cell. However, as used in this disclosure, so long as a higher-level controller or system administrator associates those physical signals with the same memory cell, and the overall combination of the address and the makeup of the memory architecture assure that a desired value can be stored and retrieved from memory, the read circuit and the write circuit can be said to read from or write to that memory cell “using” the same address.

In specific embodiments, the RAMs described herein can be integrated with a computational system including computational units in that the RAM and the computational units are formed in the same semiconductor substrate. The loops of inverters can comprise inverters that are formed of the same transistors as are used in the computational units of the processor in which the RAM is integrated. This can provide significant benefits in that the inverter is a basic building block of the computational units and is well characterized and does not need to be independently designed. Furthermore, the transistors that are used in the computational units of modern processors have benefited from semiconductor processing improvements and device level innovations such that individual inverters are now much smaller than standard RAM cells such as SRAMs.

In specific embodiments, the loops of inverters can store information in the form of values represented by oscillation states of the loops of inverters. As one example, a pattern of pulses that are circulating in a loop can determine an oscillation state of the loop of inverters and can represent one or more bits of information. As another example, a width of a pulse that is circulating in the loop can represent one or more bits of information. Various other possible oscillation states can represent values in different ways as will be described in the detailed description below.

In specific embodiments, the power consumption of individual loops of inverters can be minimized in various ways. For example, the inverters can be operated with a low supply voltage. The supply voltage supplied to the loops of inverters can be a memory supply voltage which is separate from a supply voltage that is supplied to any computational units with which the loops of inverters are integrated, and the memory supply voltage can be substantially lower than the supply voltage for the loops of inverters. The supply voltage can be equal to or less than the threshold voltage of a transistor that forms an inverter in the loop of inverters (e.g., the threshold voltage of the n-type transistor in an inverter formed by complementary transistors).

In specific embodiments, at least one neural network circuit can be trained to assist the read circuits or the write circuits to recover noisy values from the loops of inverters. The neural network could be trained to discern the appropriate control signals to use to write a desired value into a loop of inverters and to read the appropriate value from that loop of inverters. The neural network circuit could be an integrated hardware unit of the read circuits or the write circuits and be trained to learn the characteristics of the device in which it is integrated.

In specific embodiments of the invention, a RAM is provided. The RAM comprises a set of loops of inverters. The loops of inverters in the set of loops of inverters are addressable using a set of corresponding addresses. The RAM further comprises a write circuit configured to write a value to a first loop of inverters when provided with a corresponding address for the first loop of inverters. The first loop of inverters is in the set of loops of inverters and the corresponding address is in the set of corresponding addresses. The RAM further comprises a read circuit configured to read the value from the first loop of inverters when provided with the corresponding address.

In specific embodiments of the invention, another RAM is provided. The RAM comprises an array of loops of inverters. The loops of inverters in the array of loops of inverters are independently readable and independently writable using a set of corresponding addresses. The RAM further comprises at least one write circuit configured to set an oscillation state of the loops of inverters independently using the set of corresponding addresses. The RAM further comprises at least one read circuit configured to sense an oscillation state of the loops of inverters independently using the set of corresponding addresses.

In specific embodiments of the invention, another RAM is provided. The RAM comprises an array of loops of inverters. The loops of inverters in the array of loops of inverters are independently readable and independently writable using a set of corresponding addresses. The RAM further comprises a means for writing values to the loops of inverters independently using the set of corresponding addresses. The RAM further comprises a means for reading the values from the loops of inverters independently using the set of corresponding addresses.

In specific embodiments of the invention, a random access memory is provided. The random access memory comprises: a set of loops of inverters, wherein the loops of inverters in the set of loops of inverters are addressable using a set of corresponding addresses; a write circuit configured to write a value to a first loop of inverters when provided with a corresponding address for the first loop of inverters, wherein the first loop of inverters is in the set of loops of inverters and the corresponding address is in the set of corresponding addresses; and a read circuit configured to read the value from the first loop of inverters when provided with the corresponding address.

In specific embodiments of the invention, a random access memory is provided. The random access memory comprises: an array of loops of inverters wherein the loops of inverters in the array of loops of inverters are independently readable and independently writable using a set of corresponding addresses; at least one write circuit configured to set an oscillation state of the loops of inverters independently using the set of corresponding addresses; and at least one read circuit configured to sense an oscillation state of the loops of inverters independently using the set of corresponding addresses.

In specific embodiments, a random access memory is provided. The random access memory comprises: an array of loops of inverters wherein the loops of inverters in the array of loops of inverters are independently readable and independently writable using a set of corresponding addresses; a means for writing values to the loops of inverters independently using the set of corresponding addresses; and a means for reading the values from the loops of inverters independently using the set of corresponding addresses.

### BRIEF DESCRIPTION OF THE DRAWINGS

The accompanying drawings illustrate various embodiments of systems, methods, and various other aspects of the disclosure. A person with ordinary skill in the art will appreciate that the illustrated element boundaries (e.g., boxes, groups of boxes, or other shapes) in the figures represent one example of the boundaries. It may be that in some examples one element may be designed as multiple elements or that multiple elements may be designed as one element. In some examples, an element shown as an internal component of one element may be implemented as an external component in another and vice versa. Furthermore, elements may not be drawn to scale. Non-limiting and non-exhaustive descriptions are described with reference to the following drawings. The components in the figures are not necessarily to scale, emphasis instead being placed upon illustrating principles.

FIG. 1 illustrates an example of an inverter loop in a memory array in accordance with examples described herein

FIG. 2 illustrates an example of an inverter loop with a sensor that continuously monitors the inverter loop in accordance with examples described herein.

FIG. 3 illustrates an example of an inverter loop with a sensor that monitors the inverter loop at specific time intervals in accordance with examples described herein.

FIG. 4 illustrates an example of an inverter loop with multiple sensors that monitor the inverter loop at multiple signal nodes in accordance with examples described herein.

FIG. 5 illustrates a loop of inverters storing a value in the form of an oscillation state where the value is analog and the oscillation state is defined by a pattern of pulses oscillating in the loop of inverters in accordance with specific embodiments of the inventions disclosed herein.

FIG. 6 illustrates an example of an inverter loop that stores values in the form of oscillation states, where the oscillation state is defined by multiple pulses in an interval, and a counter counts the pulses in accordance with specific embodiments of the inventions disclosed herein.

FIG. 7 illustrates a loop of inverters storing a value in the form of an oscillation state where the value is analog and the oscillation state is defined by a pulse width of a pulse in the loop of inverters in accordance with specific embodiments of the inventions disclosed herein.

FIG. 8 illustrates a read circuit and a write circuit for a RAM memory array that have been augmented with a neural network encoder and a neural network decoder in accordance with specific embodiments of the inventions disclosed herein.

FIG. 9 illustrates an example of a write method and a read method in accordance with specific embodiments of the inventions disclosed herein.

### DETAILED DESCRIPTION

Reference will now be made in detail to implementations and embodiments of various aspects and variations of systems and methods described herein. Although several exemplary variations of the systems and methods are described herein, other variations of the systems and methods may include aspects of the systems and methods described herein combined in any suitable manner having combinations of all or some of the aspects described.

Methods and systems which involve computer memories are disclosed in detail herein. The methods and systems disclosed in this section are nonlimiting embodiments of the invention, are provided for explanatory purposes only, and should not be used to constrict the full scope of the invention. It is to be understood that the disclosed embodiments may or may not overlap with each other. Thus, part of one embodiment, or specific embodiments thereof, may or may not fall within the ambit of another, or specific embodiments thereof, and vice versa. Different embodiments from different aspects may be combined or practiced separately. Many different combinations and sub-combinations of the representative embodiments shown within the broad framework of this invention, that may be apparent to those skilled in the art but not explicitly shown or described, should not be construed as precluded.

Random access memories comprising a set of loops of inverters are disclosed herein. The set of loops of inverters can be arranged in an array. Each loop of inverters can comprise a memory cell in the array. Each loop of inverters can store a value associated with an oscillation state of the loop of inverters by being placed into that oscillation state by a write circuit and by having that oscillation state detected by a read circuit. As in standard memory architectures, multiple memory cells can share the same read circuit and write circuit. The read and write circuits can be addressed with specific control signals to access a given loop of inverters to write a value thereto or to read a value therefrom. The read and write circuits may use different addressing schemes so long as a higher-level controller is able to address a given cell for writing a given value and know which address to provide to read that value from that given cell when it is time to recall the value.

In specific embodiments, the inverters can be formed by transistors and can be designed to invert a signal provided at the input to an inverted signal on the output. With multiple inverters in a row and connected in a loop, the cumulative effect will be to pass a pulse from one inverter to the next around the loop with the pulse being inverted as it passes each inverter but continuing to be passed along the loop. In this state, the loop of inverters can be referred to as oscillating. The time it takes for a single pulse to circumvent the loop can be referred to as the loop time and is set by the rise and fall times of the inverter outputs and the thresholds of the inverter inputs. The thresholds can be set, in part, by threshold voltages of the transistors that make up the inverters. The rise and fall times can be set, in part, by the amount of current the transistors that make up the inverters can source from the supply voltage or sink to the reference voltage.

In embodiments in which the inverters are formed by transistors, the transistors can be field effect transistors (FETs), bipolar junction transistors (BJTs), junction field effect transistors (JFETs), or any style of transistor used to form inverter circuits. However, as described in the summary above, certain benefits accrue to approaches in which the transistors are the same type of transistors used for the logic transistors of an integrated processor. The inverters in the loops of inverters can comprise two complementary field effect transistors. The transistors can be complementary field effect transistors with: an n-type transistor source coupled to a reference voltage, drain coupled to an output of the inverter, and gate coupled to an input of the inverter; and a p-type transistor source coupled to a supply voltage, drain coupled to an output of the inverter, and gate coupled to the input of the inverter.

The loops of inverters can comprise any number of inverters in a chain with the output of the final inverter fed back to the input of the first inverter in the chain. The connections between the output and input of the inverters in the chain can be referred to as signal nodes of the inverter. Read circuits and write circuits may include control or sensing circuits coupled in series with the chain. The control or sensing circuits can serve a dual role as an inverter in the chain either continuously or in certain phases of operation. For example, a control circuit in series with a chain may be able to force a high or low value into a signal node to an input of the next inverter in the chain in a control state and act as a standard inverter in another state.

Read circuits and write circuits may include control or sensing circuits with high impedance contacts to the signal nodes to the chain for purposes of reading and writing to the inverter chain. For example, a gate of a FET in a sensing circuit such as the clock input of a flip flop (e.g., a toggle flip flop) or a counter circuit could be coupled to a signal node to determine if a pulse has moved through a signal node. The read and write circuits may alternatively or in combination be connected to circuits that isolate the transistors of the inverter that are connected to the signal nodes from a supply voltage or a reference voltage to force the state of an inverter output high, low, or to a float state.

In specific embodiments of the invention, the loops of inverters can each consist of an odd number of inverters. The inverters can be standard inverters or control or sensing circuits that can operate as inverters that are in series with the other inverters in the loop. Inverters can introduce distortions to pulses that are traveling around the loop of inverters owing to a difference in the input and output signals. Due to different rise and fall times of the output of the inverter, the width of the pulse may be modified as it passes through an inverter. For example, the mismatch in rise and fall times can be attributable, in some embodiments, to a mismatch between the n-type and p-type transistors in the inverter. However, by using an odd number of inverters in the loop, the effect of these distortions can be counter acted every other time the pulse travels through the loop. As a result, the distortions will not compound and will be cancelled out.

The RAMs disclosed herein can be integrated with a processor on the same substrate and integrated circuit. The RAMs disclosed herein can be integrated with a systolic computational array, data flow computation structure, or any form of computational circuit. Alternatively, the RAMs disclosed herein can be built on their own substrate but be packaged with alternative integrated circuits with processors in a single package. Alternatively, the RAMs disclosed herein can be stand-alone memory components on a separate integrated circuit or package. For example, the RAMs disclosed herein could be encapsulated in a chiplet designed to interoperate with alternative chiplets that may include other components such as processors. Alternatively, the RAMs can be the main components of a compute-in-memory computational system. The processors, or any computational circuits, that will utilize the RAMs disclosed herein can be part of a dedicated accelerator for machine intelligence applications, cryptography applications, or graphics processing applications, or can be part of a general central processing unit. The processors can be multicore processors.

In specific embodiments, the RAMs disclosed herein can be integrated with a processor with at least one processing core comprising computational units. The computational units can be arithmetic logic units, floating point units, or other logic. The computational units can include logic transistors that are connected together to form logic gates. The logic transistors can be FET transistors designed for rapid and efficient processing. The logic transistors can be fin-FETs, gate-all-around transistors, nanowire transistors, quantum tunnel FETs, carbon nanotube transistors, graphene and other two-dimensional material transistors, electron spin transistors, or other transistor technologies. The processor can conduct computations using a set of logic transistors where the logic transistors are any of the types of transistors mentioned above.

In specific embodiments, the loops of inverters can be formed by a set of inverter transistors. The set of inverter transistors can be the same type of transistors as the set of logic transistors mentioned in the prior paragraph. In specific embodiments, the loops of inverters can form a RAM for a processor which is integrated on the same substrate as the RAM, and the set of logic transistors for the processor and the set of inverter transistors for the set of inverters can be the same type of transistors. In specific embodiments, the loops of inverters can form a RAM for a processor which is integrated on the same substrate as the RAM, and the set of logic transistors for the processor and the set of inverter transistors for the set of inverters can be formed using a common process flow. In these embodiments, there may be minor additional steps conducted for either the logic transistors or the inverter transistors, but the core processing steps and device types for the two sets of transistors will be the same. The set of inverter transistors can be the minimum sized FETs (for the processing node) used to form the set of logic transistors. The set of inverter transistors can be the standard sized FETs used for the set of logic transistors. These embodiments will exhibit a greater degree of integration between the RAM and the logic as compared to current approaches and can result in better alignment and layout of the RAM and logic on an integrated circuit. For example, blocks of RAM transistors could be mixed in with blocks of computational logic transistors instead of having one area of a chip reserved for memory and another area of the chip reserved for logic. Furthermore, if the inverter FETs are comparable in size to the logic FETs, then the RAM will exhibit much greater density than current state of the art SRAM devices and that advantage will continue to increase as chip fabrication processes move towards smaller processing nodes.

In specific embodiments of the invention, the value stored by a loop of inverters is determined by an oscillation state of the loop of inverters which is associated with that value. A write circuit can be configured to write that value to the loop of inverters by putting the loop of inverters into that oscillation state and a read circuit can be configured to read that value by sensing that the loop of inverters is in that oscillation state. The correspondence between values and oscillation states could be assigned as desired so long as a higher-level control system had knowledge of the correspondence. Various potential oscillation states and associated read and write circuits are described in the following paragraphs.

In specific embodiments of the invention, a loop of inverters can serve as a multi-bit RAM cell. An example of this type of RAM can be referred to as a digital oscillating glitch RAM (DOGRAM). The loop of inverters could store a value in an oscillation state defined by a pattern of pulses looping through the loop. The pattern could be any type of line encoding. The pattern does not need to be a repeating pattern and can be any waveform that can be sustained on the loop of inverters through multiple loops. The pattern may or may not consume an entire loop period of the loop of inverters and the read and write circuits could be configured to ignore portions of the loop period which were not consumed by the pattern. A read circuit could be designed to detect the oscillation state by determining the pattern on the loop of inverters. A write circuit could be designed to set the oscillation state by forcing the pattern on the loop of inverters.

The pattern can be defined by a waveform on the loop of inverters in various ways. The pattern could be defined by the waveform that occurs when monitoring a given signal node of the loop of inverters over time. The pattern could be defined by the value of that waveform at specific intervals. For example, every 100 nanoseconds the voltage on a portion of a loop of inverters could be sampled and the sampled voltage values could define the pattern. If the voltages were high, a bit associated with the associated intervals would be one, while if the voltages were low, a bit associated with the associated intervals would be zero. The opposite association could also be implemented so long as a higher-level control system had knowledge of the correspondence. Alternatively, or in combination, the pattern could be defined by reading multiple points on the loop of inverters simultaneously to increase the read speed of the circuit. For example, all the signal nodes of a loop of inverters could be connected to a high impedance node capable of determining the voltage of the node at a given time and multiple portions of the waveform on the loop of inverters could be read at the same time.

The pattern of pulses could take on various forms to represent certain values. The pattern could be a number of pulses expressed by a given signal node during the loop period where the number of pulses alone stored the informational content of the pattern. Alternatively, the pattern could be a sequential pattern of high and low values expressed by a given signal node where the order of the high and low values stored the informational content of the pattern. The pattern could be any form of line code, so long as the duration of the code was less than the loop period. The pattern of pulses could utilize a non-return to zero or return to zero encoding. The pattern could include break periods between intervals to assure adequate time for a read circuit to ascertain the correct value for a given interval. The pattern could include a high or low voltage value in each interval to represent the value of that interval. The pattern could also include multiple pulses in an interval with a counter used to count the pulses in an interval. The pattern of pulses could include the duration for which each voltage value at a specific point on the loop of inverters was maintained. To minimize power consumption, the encoding could be designed to minimize the number of pulse edges traveling through an inverter per bit of information stored. The encoding may also be designed to use larger pulse widths to make accurate reading of the pulses and their continued oscillations less sensitive to noise.

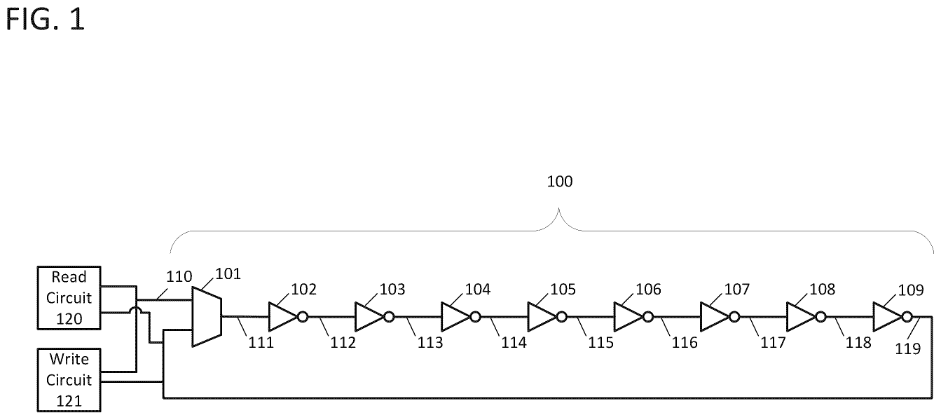

FIG. 1 illustrates an example of inverter loop 100 in a memory array in accordance with examples described herein. Inverter loop 100 may include inverters 101 through 109, signal nodes 111 through 119, inverter loop input 110, read circuit 120, and write circuit 121. Inverter 101 may act as control or sensing circuits in some modes of operation and as a normal inverter in other modes of operation.

An inverter loop can comprise any number of inverters in a chain, although nine inverters (inverters 101, 102, 103, 104, 105, 106, 107, 108, and 109) are shown in inverter loop 100. Each output of an inverter is fed into the input of the next inverter. For example, the output of inverter 101 is fed into the input of inverter 102, the output of inverter 102 is fed into the input of inverter 103, etc. The output of the final inverter 109 is fed back to the input of the first inverter 101 in the chain. The connections between the output and input of the inverters in the chain can be referred to as signal nodes (e.g., signal nodes 111 through 119) of the inverter (e.g., of inverters 101 through 109). For example, signal node 111 may be between inverter 101 and inverter 102 (and correspond to the output of inverter 101), signal node 112 may be between inverter 102 and inverter 103 (and correspond to the output of inverter 102), etc. with signal nodes 113, 114, 115, 116, 117, 118, and 119.

In specific embodiments of the invention, the loops of inverters can each consist of an odd number of inverters (as shown). The inverters can be standard inverters (e.g., inverters 102 through 109) or control or sensing circuits that can operate as inverters (e.g., inverter 101) that are in series with the other inverters in the loop. In some cases, inverters may introduce distortions to pulses that are traveling around the loop of inverters owing to a difference in the input and output signals. Due to different rise and fall times of the output of the inverter, the width of the pulse may be modified as it passes through an inverter. For example, the mismatch in rise and fall times can be attributable, in some embodiments, to a mismatch between the n-type and p-type transistors in the inverter. However, by using an odd number of inverters in the loop, the effect of these distortions can be counter acted every other time the pulse travels through the loop. As a result, the distortions will not compound, but be cancelled out instead.

Read circuit 120 and write circuit 121 (or multiple read circuits and write circuits) may include control or sensing circuits coupled in series with the chain. The control or sensing circuits can serve a dual role as an inverter (e.g., inverter 101) in the chain either continuously or in certain phases of operation. For example, a control circuit in series with a chain (e.g., as inverter 101) may be able to force a high or low value into a signal node (e.g., signal node 111) to an input of the next inverter (e.g., inverter 102) in the chain in a control state. The control circuit in series with the chain may act as a standard inverter in another state (e.g., as inverter loop 100 oscillates and stores the written pulse pattern). Read circuit 120 and write circuit 121 may include control or sensing circuits with high impedance contacts to the signal nodes (e.g., signal node 119) to the chain for purposes of reading and writing to the inverter chain. For example, a gate of a FET in a sensing circuit such as the clock input of a flip flop (e.g., a toggle flip flop) or a counter circuit could be coupled to a signal node to determine if a pulse has moved through a signal node. The read circuit 120 and write circuit 121 may alternatively or in combination be connected to circuits that isolate the transistors of the inverter that are connected to the signal nodes from a supply voltage or a reference voltage to force the state of an inverter output high, low, or to a float state.

In specific embodiments of the invention, the value stored by inverter loop 100 is determined by an oscillation state of the chain of inverters. For example, the oscillation state stores or corresponds to the value. Write circuit 121 can be configured to write that value to the loop of inverters by putting the loop of inverters into that oscillation state. Read circuit 120 can be configured to read that value by sensing that the loop of inverters is in the oscillation state that corresponds to that value. The correspondence between values and oscillation states could be assigned as desired so long as a higher-level control system had knowledge of the correspondence. Various potential oscillation states and associated read and write circuits are described in the following paragraphs.

In specific embodiments of the invention, inverter loop 100 can serve as a multi-bit RAM cell. An example of this type of RAM can be referred to as a digital oscillating glitch RAM (DOGRAM). Inverter loop 100 could store a value in an oscillation state defined by a pattern of pulses looping through inverter loop 100. The pattern could be any type of line encoding. The pattern does not need to be a repeating pattern and can be any waveform that can be sustained on inverter loop 100 through multiple loops. The pattern may or may not consume an entire loop period of inverter loop 100. Read circuit 120 and write circuit 121 could be configured to ignore portions of the loop period which were not consumed by the pattern. Read circuit 120 could be designed to detect the oscillation state by determining the pattern on inverter loop 100. Write circuit 121 could be designed to set the oscillation state by forcing the pattern on inverter loop 100.

The pattern can be defined by a waveform on inverter loop 100 in various ways. The pattern may be defined by the waveform that occurs when monitoring a given signal node of inverter loop 100 over time. The pattern could be defined by the value of that waveform at specific intervals. For example, every 100 nanoseconds the voltage on a portion of inverter loop 100 could be sampled and the sampled voltage values could define the pattern. If the voltages are high, a bit associated with the associated intervals may be one, while if the voltages are low, a bit associated with the associated intervals may be zero. The opposite association could also be implemented so long as a higher-level control system had knowledge of the correspondence. Alternatively, or in combination, the pattern may be defined by reading (via one or more read circuits such as read circuit 120) multiple points on inverter loop 100 simultaneously to increase the read speed of the read circuit. For example, all signal nodes 111 through 119 of inverter loop 100 could be connected to high impedance nodes capable of determining the voltage of each of signal nodes 111 through 119 at a given time and multiple portions of the waveform on inverter loop 100 could be read at the same time.

The pattern of pulses may take on various forms to represent certain values. The pattern may be a number of pulses expressed by a given signal node during the loop period where the number of pulses alone stores the informational content of the pattern. Alternatively, the pattern could be a sequential pattern of high and low values expressed by a given signal node (e.g., one of signal nodes 111 through 119) where the order of the high and low values stores the informational content of the pattern. The pattern could be any form of line code, so long as the duration of the code is less than the duration of the loop period. The pattern of pulses could utilize a non-return to zero or return to zero encoding. The pattern could include break periods between intervals to assure adequate time for read circuit 120 to ascertain the correct value for a given interval. The pattern could include a high or low voltage value in each interval to represent the value of that interval. The pattern could also include multiple pulses in an interval with a counter used to count the pulses in an interval. The pattern of pulses could include the duration for which each voltage value at a specific point on the loop of inverters was maintained (e.g., voltage pulse width). To minimize power consumption, the encoding could be designed to minimize the number of pulse edges traveling through an inverter per bit of information stored. The encoding may also be designed to use larger pulse widths to make accurate reading of the pulses and their continued oscillations less sensitive to noise.

Read circuit 120, in the case of oscillation states in the form of different patterns of pulses, can include a high impedance connection to a signal node in the loop of inverters. Read circuit 120 can comprise a clock data recovery circuit. Detecting the pattern of pulses can comprise measuring a voltage on inverter loop 100 according to a set of fixed time intervals using the clock data recovery circuit. Detecting the pattern of pulses can also comprise measuring a voltage on inverter loop 100 according to a set of fixed time intervals using a latch and a clock circuit set to pulse according to the time intervals. If the pattern is a simple number of pulses and the order of high and low values is not an aspect that distinguishes the pattern from other oscillation states that represent alternative values, read circuit 120 can be (or include) a simple counter circuit that counts the number of pulses. Read circuit 120 can include an oscillator, with the oscillator being coupled to the counter circuit. The oscillator may have a period that is substantially shorter than the loop period of inverter loop 100. Read circuits (e.g., including read circuit 120 and other read circuits) in the case of reading off multiple signal nodes simultaneously, can involve multiple copies of such circuits with inputs connected to the associated signal node.

Write circuit 121, in the case of oscillation states in the form of different patterns of pulses, can take on various forms. Write circuit 121 can be configured to break the ring oscillator feedback, such as by using a control circuit (e.g., inverter 101) in series with the other inverters in the loop, or a control circuit that can pull specific inverter outputs to the reference voltage or supply voltage. Write circuit 121 can also be configured to flush the signal nodes (e.g., signal nodes 111 through 119) to a constant value, such as zero or one. Flushing the signal nodes may involve forcing inverter loop input 110 to the constant value (e.g., breaking the feedback) and holding the constant value for the duration of the loop period. Write circuit 121 can also be configured to inject the pattern into inverter loop 100 by pulling a signal node (e.g., signal node 119) down to a reference voltage and back up to the supply voltage repeatedly in accordance with the pattern. Write circuit 121 can also be configured to close the feedback for inverter loop 100 after forcing the signal node to the final value of the pattern.

In specific embodiments, the power consumption of inverter loop 100 can be minimized by minimizing the frequency of inverter switching in inverter loop 100 per bit stored by inverter loop 100. The loop period of inverter loop 100 can be kept long with a minimal number of inverters in the loop in order to decrease the frequency of inverter switching required to store a value for a given time. At the same time, the loop period can be kept low enough to ensure rapid read times for read circuits (e.g., read circuit 120) that sample at one, or a limited number, of signal nodes on inverter loop 100. The supply voltage of the inverters can also be kept low such that they do not consume as much power regardless of their switching speed. Both above approaches can also be combined. For example, the number of inverters in inverter loops (such as inverter loop 100) may be minimized and be set to a low number such as 3 or 5 inverters and the inverters can be held at an operating point that will assure slower switching speeds such as by using narrow channel transistors, low reference voltages, or low supply currents.

In specific embodiments, the power consumption of individual loops of inverters (such as inverter loop 100) may be minimized by operating the inverters at a low supply voltage. As power consumption is directly proportional to voltage, a reduced supply voltage will reduce the amount of power consumed by the loop of inverters. For example, the inverters can be operated with a low supply voltage. The supply voltage supplied to the loops of inverters can be a memory supply voltage which is separate from a supply voltage that is supplied to any computational units with which the loops of inverters are integrated, and the memory supply voltage can be substantially lower than the supply voltage for the loops of inverters. The supply voltage can be equal to or less than the threshold voltage of a transistor that forms an inverter in the loop of inverters (e.g., the threshold voltage of the n-type inverter in an inverter formed by complementary transistors).

In specific embodiments, the oscillation state can include line encoding of a “start” code which indicates where a stored value of the inverter chain begins. For example, the start code could be a pulse having a width that is wider or narrower than the pulses which are used for the bit values stored by the inverter chain. As another example, the start code could be an illegal series of values for the pulses which are used for the bit values stored by the inverter chain. In these embodiments, multiple signal nodes of the inverter chain could be read in parallel with the start code indicating where the line encoding should be read from. In embodiments having a large chain of inverters, the read time could be significantly accelerated using this technique. The read circuits of the RAM could be configured to translate the read value into the actual stored value using knowledge of the start code and a hard coded logic circuit.

In specific embodiments of the invention, the supply voltage for the inverters can be comparable to the threshold voltages of the transistors that form the inverters. For example, in specific embodiments in which the inverters include a pair of transistors and the pair of transistors have a pair of threshold voltages, the memory supply voltage can be equal to or less than a sum of the pair of threshold voltages at room temperature. For example, an n-type transistor with a threshold voltage of 250 milli-volts and a p-type transistor with a threshold voltage of 200 milli-volts that are connected in series between the supply voltage and a reference voltage to form an inverter can be operated with a supply voltage of 450 milli-volts. The memory supply voltage can be designed to increase with a decrease in temperature to accommodate the change in threshold voltages of the transistors as temperature changes.

Systems in accordance with this disclosure in which the RAM formed of loops of inverters is integrated with a processor having logic transistors can include a memory array voltage regulator that provides a memory supply voltage to the loops of inverters in the array of loops of inverters. The system can also include a supply voltage for the logic transistors of the processor. The memory supply voltage can be derived from the supply voltage for the logic transistors in that the supply voltage for the logic transistors is an input to the memory array voltage regulator. The supply voltage for the logic transistors can be greater than the memory supply voltage. For example, the supply voltage for the logic transistors can be greater than 1 volt and the memory supply voltage can be less than 500 milli-volts.

In specific embodiments, the power consumption of individual loops of inverters can be minimized by using the minimal sized logic transistors for a given processing node in which the loop of inverters is implemented. As process nodes continue to shrink the amount of charge required to influence the gates of the logic transistors decreases (i.e., the size of the gate capacitance decreases). Also, the supply voltage required to operate the logic transistors decreases. As a result, approaches in which the transistors that form the loops of inverters are the same as, or similar to, the transistors used for the computational circuits of the system in which they are integrated will naturally express improved performance in power consumption in the future as processing nodes continue to shrink and improve.

In specific embodiments, at least one neural network circuit can be trained to assist the read circuits or the write circuits to recover noisy values from the loops of inverters. The write circuits assist in recovering noisy values from the loops of inverters by modifying the manner in which the written values are stored to the memory. The neural network could be trained to discern the appropriate control signals to use to write a desired value into a loop of inverters and to read the appropriate value from that loop of inverters. The neural network circuit could be an integrated hardware unit of the read circuits or the write circuits and be trained to learn the characteristics of the device in which it is integrated. Noisy values can be read from the loops of inverters and the neural networks can be trained to recover exact values. Additionally, altered values can be written to the loops of inverters using a neural network that is trained to counteract the impact of noise from the writing and storage of information in the array. An encoding neural network can form part of the write circuits disclosed herein. A decoding neural network can form part of the read circuits disclosed herein.

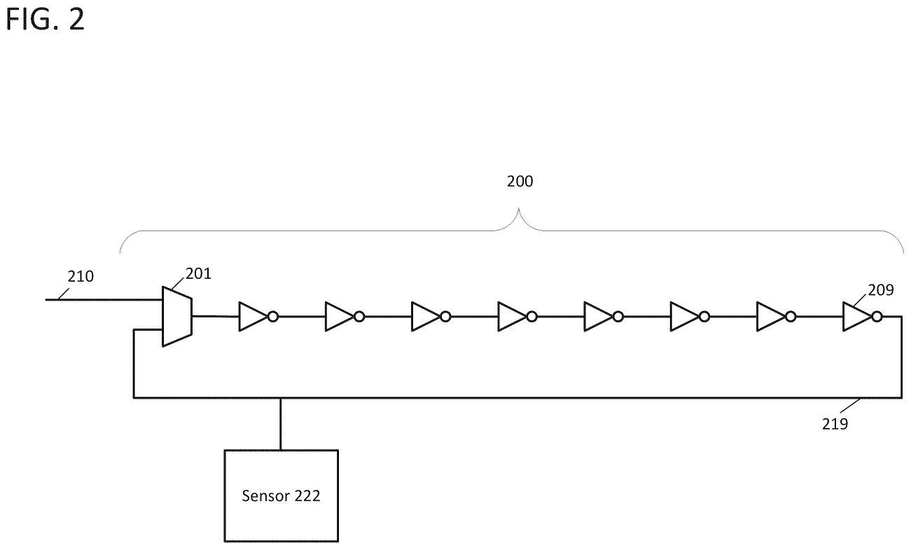

FIG. 2 illustrates an example of inverter loop 200 with sensor 222 that continuously monitors inverter loop 200 in accordance with examples described herein. Inverter loop 200 may include features similar to those of inverter loop 100. Inverter loop 200 may include inverters 201 and 209 (and other inverters), signal node 219 (among others), inverter loop input 210, and sensor 222. Inverter 201 may act as a control or sensing circuit in some modes of operation and as a normal inverter in other modes of operation of inverter loop 200. Each output of an inverter is fed into the input of the next inverter. The connections between the output and input of the inverters in the chain may be signal nodes of the inverter.

In specific embodiments of the invention, inverter loop 200 may serve as a multi-bit RAM cell (e.g., DOGRAM). Inverter loop 200 may store a value in an oscillation state defined by a pattern of pulses looping through the loop. The pattern could be any type of line encoding. The pattern does not need to be a repeating pattern and can be any waveform that can be sustained on inverter loop 200 through multiple loops. The pattern may or may not consume an entire loop period of the loop of inverters and read and write circuits could be configured to ignore portions of the loop period which were not consumed by the pattern. A read circuit could be designed to detect the oscillation state by determining the pattern on the loop of inverters. A write circuit could be designed to set the oscillation state by forcing the pattern on the loop of inverters.

The pattern can be defined by a waveform on the loop of inverters in various ways. The pattern could be defined by the waveform that occurs when monitoring (e.g., continuously monitoring) a given signal node of the loop of inverters over time. The monitoring may be split into distinct intervals. An interval may correspond to the duration of the loop period or may refer to a shorter time duration (e.g., a percentage or fraction of the loop period). In specific embodiments, sensor 222 continuously monitors signal node 219. A high voltage over an interval may signify that a bit associated with the interval is one. A low voltage over an interval may signify that a bit associated with the interval is zero. The opposite association could also be implemented so long as a higher-level control system had knowledge of the correspondence. Sensor 222 may be coupled with or be part of a read circuit that reads or detects the oscillation state of inverter loop 200. The one or more values (e.g., one or more bits) stored by inverter loop 200 may be read based on information gathered by sensor 222. In specific embodiments, multiple bits may be read based on a single oscillation state or waveform.

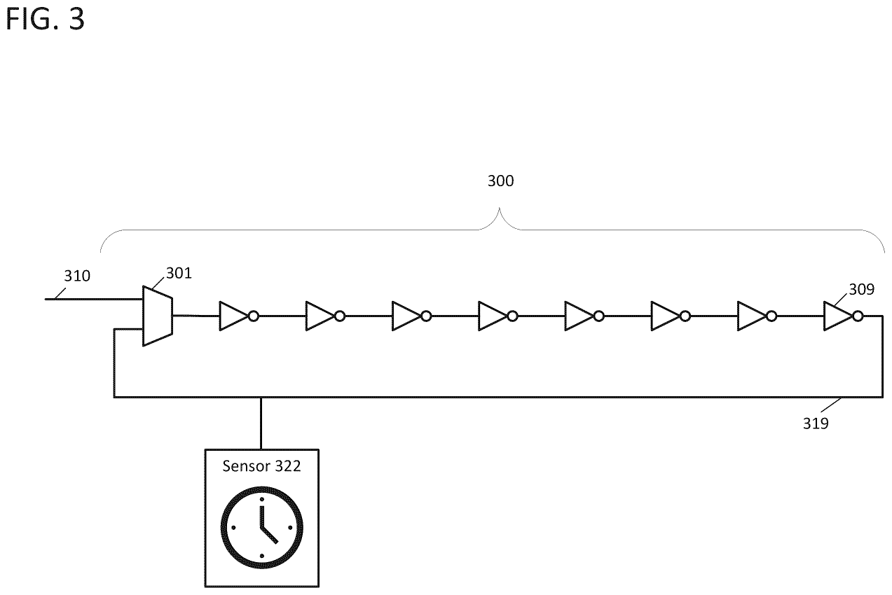

FIG. 3 illustrates an example of inverter loop 300 with sensor 322 that monitors inverter loop 300 at specific time intervals in accordance with examples described herein. Inverter loop 300 may include features similar to those of inverter loop 100 and/or those of inverter loop 200. Inverter loop 300 may include inverters 301 and 309 (and other inverters), signal node 319 (among others), inverter loop input 310, and sensor 322. Inverter 301 may act as a control or sensing circuit in some modes of operation and as a normal inverter in other modes of operation. Each output of an inverter is fed into the input of the next inverter of the loop. The connections between the output and input of the inverters in the chain may be signal nodes of inverter loop 300.

In specific embodiments of the invention, inverter loop 300 may serve as a multi-bit RAM cell (e.g., DOGRAM). Inverter loop 300 may store a value in an oscillation state defined by a pattern of pulses looping through the loop. The pattern could be any type of line encoding. The pattern does not need to be a repeating pattern and can be any waveform that can be sustained on inverter loop 300 through multiple loops. The pattern may or may not consume an entire loop period of inverter loop 300 and read and write circuits could be configured to ignore portions of the loop period which were not consumed by the pattern. A read circuit may detect the oscillation state by determining the pattern on inverter loop 300. A write circuit may set the oscillation state by forcing the pattern on inverter loop 300.

The pattern may be defined by a waveform on the loop of inverters in various ways. The pattern may be defined by the value of that waveform at specific intervals. For example, every 100 nanoseconds the voltage on a portion of a loop of inverters may be sampled and the sampled voltage values could define the pattern. An interval may correspond to the duration of the loop period or may refer to a shorter time duration (e.g., a percentage or fraction of the loop period). If the sampled voltage is high, a bit associated with the associated intervals may be one, while if the voltage is low, a bit associated with the associated interval may be zero. The opposite association could also be implemented so long as a higher-level control system had knowledge of the correspondence.

In specific embodiments, multiple voltage samplings may be associated with a single bit. For example, if sensor 322 monitors signal node 319 multiple times and each of the voltages are high, the bit(s) associated with the associated intervals would be one, while if each of the voltages are low, the bit(s) associated with the associated intervals would be zero. In specific examples, a mix of high and low voltages may correspond to an error. In specific examples, a mix of high and low voltages may correspond to a value (e.g., a multibit value).

In specific embodiments, sensors 322 monitors signal node 319 at specific time intervals (e.g., samples the voltage every 100 ns). Sensor 322 may be coupled with or be part of one or more read circuits that read or detect the oscillation state of inverter loop 300. The one or more values (e.g., one or more bits) stored by inverter loop 300 may be read based on information gathered by sensor 322. In specific embodiments, multiple bits may be read based on a single oscillation state or waveform.

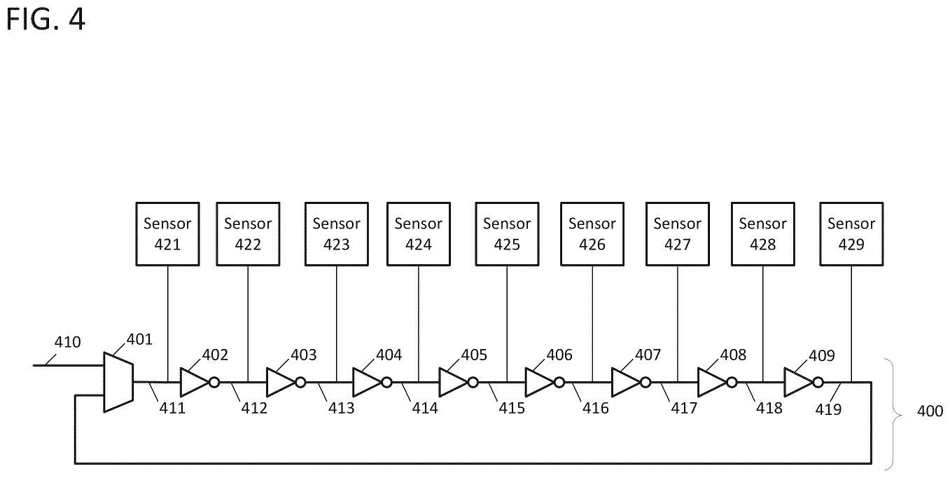

FIG. 4 illustrates an example of inverter loop 400 with multiple sensors (sensors 421 through 429) that monitor inverter loop 400 at multiple signal nodes (signal nodes 411 through 419) in accordance with examples described herein. Inverter loop 400 may include features similar to those of inverter loops 100, 200, and/or 300. Inverter loop 400 may include inverters 401, 402, 403, 404, 405, 406, 407, 408, and 409; signal nodes 411, 412, 413, 415, 416, 417, 418, and 419; sensors 421, 422, 423, 424, 425, 426, 427, 428, and 429; and inverter loop input 410. Inverter 401 may act as a control or sensing circuit in some modes of operation and as a normal inverter in other modes of operation. Each output of an inverter is fed into the input of the next inverter of the loop. The connections between the output and input of the inverters in the chain may be signal nodes (e.g., signal nodes 411 through 419). Sensors may detect voltages at the signal nodes. For example, sensor 421 may measure the voltage of signal node 411, corresponding to the output of inverter 401. Sensor 422 may measure the voltage of signal node 412, corresponding to the output of inverter 402. Sensor 423 may measure the voltage of signal node 413, corresponding to the output of inverter 403. Similarly, sensors 424, 425, 426, 427, 428, and 429 may measure voltages associated with signal nodes 414, 415, 416, 417, 418, and 419 respectively.

Using multiple sensors 421 through 429 may increase the reading speed of inverter loop 400, compared to an inverter loop with fewer sensors. The read circuit can include a counter to count a number of pulses. The read circuit may include a clock to read voltages at specific times (e.g., specific time intervals). The read circuit may involve multiple copies of such circuits with inputs connected to the associated signal node.

In specific embodiments, not all sensors 421 through 429 may be present in inverter loop 400. In other words, not every signal node 411 through 419 may be associated with a sensor. For example, sensors 422, 424, 426, and 428 may detect voltages associated with signal nodes 412, 414, 416, and 418 respectively, while signal nodes 411, 413, 415, 417, and 419 are not associated with any sensors (e.g., there are no sensors 421, 423, 425, 427, or 429).

In specific embodiments of the invention, inverter loop 400 may serve as a multi-bit RAM cell (e.g., DOGRAM). Inverter loop 400 may store a value in an oscillation state defined by a pattern of pulses looping through the loop. The pattern could be any type of line encoding. The pattern does not need to be a repeating pattern and can be any waveform that can be sustained on inverter loop 400 through multiple loops. The pattern may or may not consume an entire loop period of inverter loop 400 and read and write circuits could be configured to ignore portions of the loop period which were not consumed by the pattern. A read circuit may detect the oscillation state by determining the pulse pattern of inverter loop 400. A write circuit may set the oscillation state by forcing the pulse pattern on inverter loop 400.

The pattern may be defined by a waveform on the loop of inverters in various ways. The pattern could be defined by reading multiple points on inverter loop 400 simultaneously to increase the read speed of the circuit. For example, all the signal nodes of a loop of inverters could be connected to a high impedance node capable of determining the voltage of the node at a given time and multiple portions of the waveform on the loop of inverters could be read at the same time.

If the sampled voltage is high, a bit associated with the associated intervals may be one, while if the voltage is low, a bit associated with the associated interval may be zero. The opposite association could also be implemented so long as a higher-level control system had knowledge of the correspondence.

In specific embodiments, multiple voltage samplings may be associated with a single bit. For example, if sensor 421 monitors signal node 411 and sensor 426 monitors signal node 416 and each of the voltages are high, a bit associated with the associated intervals would be one, while if each of the voltages are low, a bit associated with the associated intervals would be zero. Sensor 421 and sensor 426 may measure their corresponding signal nodes at the same time or may offset their measurements (e.g., so that the offset matches the speed at which the pulse travels through inverter loop 400. In specific examples, a mix of high and low voltages may correspond to an error. In specific examples, a mix of high and low voltages may correspond to a value (e.g., a multibit value).

In specific embodiments, sensors 421 through 429 monitor their corresponding signal nodes 411 through 419 at specific time intervals. A time interval may correspond to the duration of the loop period or may refer to a shorter time duration (e.g., a percentage or fraction of the loop period). A time interval may correspond to a duration of time (or a multiple of the duration of time) related to a reaction of an inverter in inverter loop 400.

In specific embodiments, sensors 421 through 429 monitor signal node 411 through 419 respectively at specific time intervals (e.g., samples the voltage at sensing node 411 every 100 ns). Sensors 421 through 429 may be coupled with or be part of one or more read circuits that read or detect the oscillation state (or portions of the oscillation state) of inverter loop 400.

The one or more values (e.g., one or more bits) stored by inverter loop 400 may be read based on information gathered by one or more of sensors 421 through 429. In specific embodiments, multiple bits may be read based on a single oscillation state or waveform.

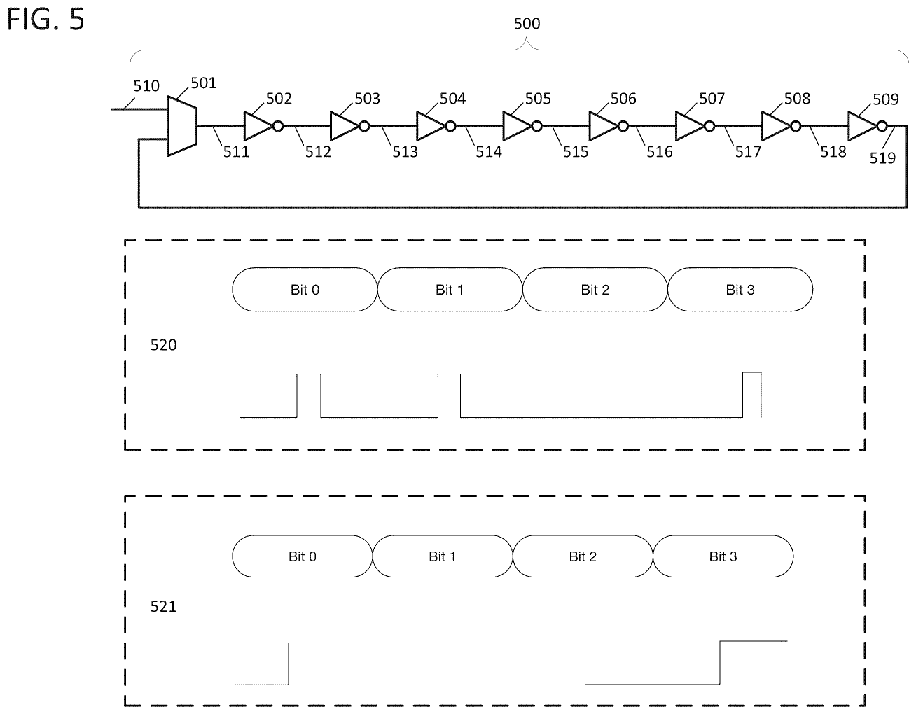

FIG. 5 illustrates an example of inverter loop 500 that stores values in the form of an oscillation state where the oscillation state is defined by a high or low voltage in each interval in accordance with examples described herein. Inverter loop 500 can serve as a single cell in a DOGRAM. Inverter loop 500 may include features similar to those of inverter loops 100, 200, 300, and/or 400. Inverter loop 500 includes eight standard inverters (inverters 502, 503, 504, 505, 506, 507, 508, and 509) and a control circuit 501 in the form of an inverting multiplexer in series with the standard inverters 502 through 509. The result is a loop of nine inverters. The multiplexer can serve as part of the write circuit for inverter loop 500. Inverter loop 500 may include input 510, which may be part of the write circuit. Inverter loop 500 may also include signal nodes 511, 512, 513, 514, 515, 516, 517, 518, and 519.

The oscillation state may refer to a pattern of pulses. The pattern of pulses could take on various forms to represent certain values. The pattern could be a sequential pattern of high and low values expressed by a given signal node where the order of the high and low values stored the informational content of the pattern. The pattern could be any form of line code so long as the duration of the code was less than the loop period. The pattern of pulses could utilize a non-return to zero or return to zero encoding. The pattern could include break periods between intervals to assure adequate time for a read circuit to ascertain the correct value for a given interval. The pattern could include a high or low voltage value in each interval to represent the value of that interval. To minimize power consumption, the encoding could be designed to minimize the number of pulse edges traveling through an inverter per bit of information stored. The encoding should also be designed to use larger pulse widths to make accurate reading of the pulses and their continued oscillations less sensitive to noise.

Also illustrated are two potential oscillation states 520 and 521 with patterns that can encode the value associated with and stored by inverter loop 500. Oscillation state 520 is a return to zero encoding in which a pulse up to a high value in a given interval is used to represent a value while the absence of a pulse away from a low value in a given interval is used to represent a different value. Oscillation state 521 is a non-return-to-zero encoding in which pulses stay high and the signal does not return to zero unless a given interval is used to represent a low value. These line encodings, and many others, can be maintained by inverter loop 500 so long as the temporal length of the encoding is less than the loop period. The informational content of the encoding is set by the number of intervals. As illustrated, there are four intervals in the illustrated circuit meaning that the loop of inverters can store four bits of information (e.g., 1101).

The read circuit, in the case of oscillation states in the form of different patterns of pulses, can include a high impedance connection to a signal node in inverter loop 500. The read circuit can comprise a clock data recovery circuit. Detecting the pattern of pulses can comprise measuring a voltage on inverter loop 500 (e.g., via one or more signal nodes 511 through 519) according to a set of fixed time intervals using the clock data recovery circuit. Detecting the pattern of pulses can also comprise measuring a voltage on inverter loop 500 (e.g., via one or more signal nodes 511 through 519) according to a set of fixed time intervals using a latch and a clock circuit set to pulse according to the time intervals. If the pattern is a simple number of pulses and the order of high and low values is not an aspect that distinguishes the pattern from other oscillation states that represent alternative values, the read circuit can be a simple counter circuit that counts the number of pulses. The read circuit can alternatively include a counter to count the number of pulses. Read circuits, in the case of reading off multiple signal nodes simultaneously, can involve multiple copies of such circuits with inputs connected to the associated signal node.

The write circuit, in the case of oscillation states in the form of different patterns of pulses, can take on various forms. The write circuit can be configured to break the ring oscillator feedback, such as by using control circuit 501 in series with inverters 502 through 509 of inverter loop 500, or a control circuit that can pull specific inverter outputs to the reference voltage or supply voltage. The write circuit can also be configured to flush signal nodes 511 through 519 to a constant value (such as zero or one) which can involve monitoring input 510 or another input to a portion of the ring oscillator with the broken feedback and holding for the constant value to be provided for the loop period. The write circuit can also be configured to inject the pattern into inverter loop 500 by pulling a signal node down to a reference voltage and back up to the supply voltage repeatedly in accordance with the pattern. The write circuit can also be configured to close the feedback for inverter loop 500 after forcing the signal node to the final value of the pattern.

In specific embodiments of the invention, a loop of inverters can serve as a multi-bit RAM cell. An example of this type of RAM can be referred to as oscillating pulse RAM (OPRAM). Inverter loop 500 could store a value in an oscillation state defined by a pulse width of a pulse on the loop of inverters or the pulse widths of multiple pulses on the loop of inverters. The pulse widths could be associated with specific values such that the single pulse allowed the loop of inverters to be a multibit memory cell with the number of bits set by a read circuit's ability to discern different pulse widths. Neural network encoders and decoders could be used to write and read the values from the loops of inverters.

A write circuit could include control circuit 501 in series with inverters 502 through 509 in inverter loop 500. The write circuit could be designed to force a signal node (e.g., signal node 519) to a low value for the loop period plus a margin of error to make sure the loop is completely flushed, then force the signal node to a high value, and to then measure the time it takes for the altered signal to circumvent the loop and reach the signal node (e.g., signal node 519) just prior to the signal node being forced to the high value. The write circuit could use that measurement to determine the loop period and could then send in a pulse that was a percentage of that number. Alternatively, the write circuit could be designed to flush the loop and then enter a pulse with a fixed time period where the fixed period was associated with the value that was intended to be stored in inverter loop 500.

A read circuit could include control circuit 501 with a high impedance connection to a signal node (e.g., signal node 519) in inverter loop 500 and a counter to determine the pulse width. The counter could be a fast oscillator with an oscillation frequency that is substantially higher than the frequency of the loop of inverters. The oscillation frequency will set a fundamental limit on the differences in pulse widths that can be detected by the read circuit.

In specific embodiments, inverter loop 500 may be programmed and read in various ways, allowing flexibility and reliability in memory storage, while the hardware (e.g., inverter loops) that store the memory is relatively small and may be integrated into computational units. In specific embodiments, inverter loop 500 may have low power consumption and may store values efficiently.

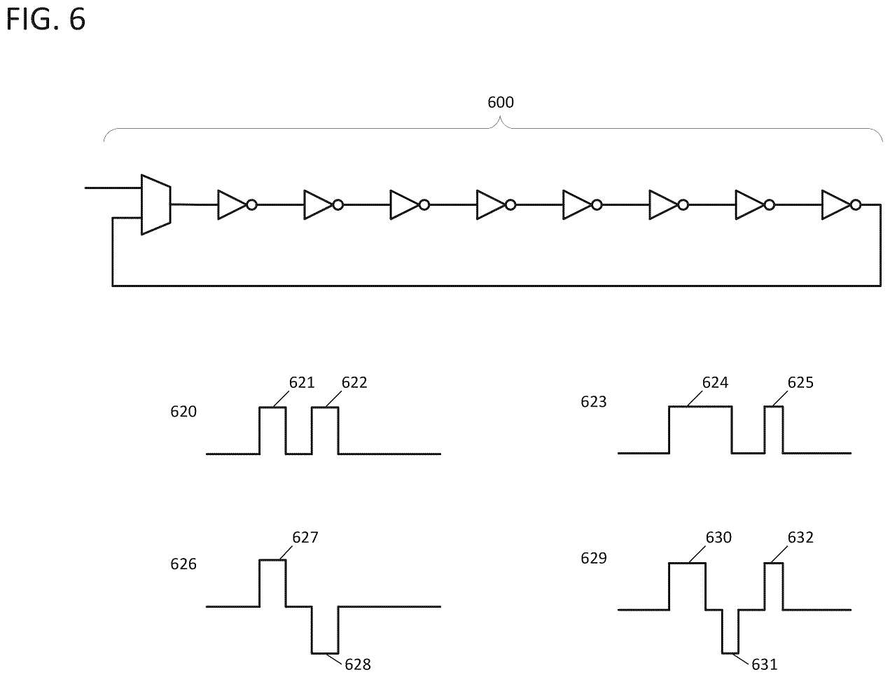

FIG. 6 illustrates an example of inverter loop 600 that stores values in the form of oscillation states where the oscillation state is defined by multiple pulses in an interval and a counter counts the pulses in accordance with examples described herein. Inverter loop 600 can serve as a single cell in a DOGRAM. Inverter loop 600 may include features similar to those of inverter loop 100, inverter loop 200, inverter loop 300, inverter loop 400 and/or inverter loop 500. Sensors may detect voltages at the signal nodes.

The oscillation state may refer to a pattern of pulses. The pattern of pulses could take on various forms to represent certain values. In specific embodiments, whether or not inverter loop 600 oscillates at all may correspond to the value stored by inverter loop 600. For example, if inverter loop 600 alternates between high and low voltage in a time period shorter than the loop period, then inverter loop 600 may store a one. If inverter loop 600 alternates between high and low voltages in a time period corresponding to the loop period, then inverter loop 600 may store a zero.

In specific embodiments, the pattern could be a number of pulses expressed by a given signal node during the loop period where the number of pulses alone stored the informational content of the pattern. In other words, the number of pulses of inverter loop 500 during the duration of an interval may correspond to a multibit value. The pattern could be any form of line code so long as the duration of the code was less than the loop period. The pattern could include break periods between intervals to assure adequate time for a read circuit to ascertain the correct value for a given interval. The pattern could include multiple pulses in an interval with a counter used to count the pulses in an interval. To minimize power consumption, the encoding could be designed to minimize the number of pulse edges traveling through an inverter per bit of information stored. The encoding may also be designed to use larger pulse widths to make accurate reading of the pulses and their continued oscillations less sensitive to noise.

Pulse patterns 620, 623, 626, and 629 show different voltage patterns over an interval. The interval may correspond to a loop period or may have a duration less than a loop period. Inverter loop 600, for example, may store one or more pulse patterns 620, 623, 626, or 629. In different embodiments, the counter may read two pulses from each pulse pattern 620, 623, 626, and 629.

Pulse pattern 620 includes two high voltage pulses 621 and 622, roughly equal in width. The counter may count two voltage pulses. Alternatively, a pulse pattern could include two low voltage pulses, which the counter may similarly count as two voltage pulses. In specific embodiments, only high voltage pulses or only low voltage pulses may be present. In specific embodiments, there may be only two values—high and low—and there may not be a middle baseline voltage.

In specific embodiments, the pulses may be wide or narrow or each pulse within an interval may have different widths. For example, pulse pattern 623 includes voltage pulses 624 and 625. Voltage pulse 624 has a wider width than voltage pulse 625. The counter may not measure (e.g., may refrain from measuring) the width of the pulses and instead count just the number of pulses. Accordingly, despite voltage pulse 624 being wider than voltage pulse 625, the counter may still count two voltage pulses.

In specific embodiments, the counter may count both high and low voltages as a pulse. In specific embodiments, there may be a middle baseline voltage between the high and low voltages. For example, pulse pattern 626 includes voltage pulses 627 and 628. Voltage pulse 627 may be a positive voltage pulse while voltage pulse 628 may be a low (e.g., negative) voltage pulse. The counter may not distinguish (e.g., may refrain from distinguishing) between high and low pulses and may count just the number of pulses. Accordingly, despite voltage pulse 627 being positive while voltage pulse 628 is negative relative to a baseline, the counter may still count two voltage pulses.

In specific embodiments, the counter may only count high voltages or only count low voltages as pulses. For example, pulse pattern 629 includes voltage pulses 630, 631, and 632. Voltage pulses 630 and 632 may be positive voltage pulses relative to a baseline while voltage pulse 632 may be a low (e.g., negative) voltage pulse. The counter may not (e.g., may refrain from) counting low pulses and may count just the number of high voltage pulses. Accordingly, the counter may ignore low voltage pulse 631 and count two voltage pulses (voltage pulses 630 and 632).

In specific embodiments, inverter loop 600 may be programmed and read in various ways, allowing flexibility and reliability in memory storage, while the hardware (e.g., inverter loop 600) that stores the memory is relatively small and may be integrated into computational units. In specific embodiments, inverter loop 600 may have low power consumption and may store values efficiently.

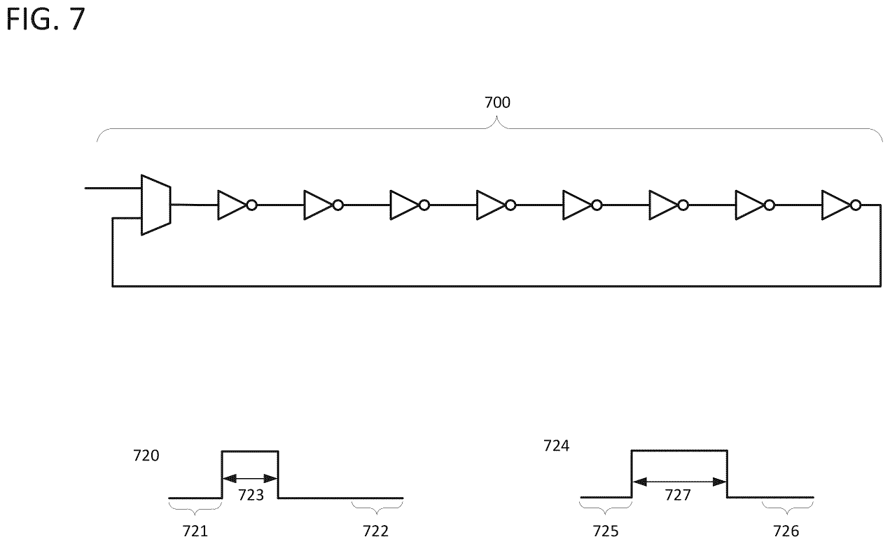

FIG. 7 illustrates inverter loop 700 storing a value in the form of an oscillation state where the value is analog and the oscillation state is defined by a pulse width of a pulse in inverter loop 700 in accordance with specific embodiments of the inventions disclosed herein. The pulses could be expressed by a signal node on inverter loop 700. The oscillation state may refer to a pattern of pulses.

The pattern of pulses could take on various forms to represent certain values. The pattern could be a number of pulses expressed by a given signal node during the loop period. The pattern could be any form of line code so long as the duration of the code was less than the loop period. The pattern could include break periods between intervals to assure adequate time for a read circuit to ascertain the correct value for a given interval. In other words, the pulses could include a preamble and postamble to allow a read circuit time to prepare to measure a pulse width and to reset in-between pulses read. For example, pulse 720 (with pulse width 723) includes preamble 721 and postamble 722. Pulse 724 (with pulse width 727) includes preamble 725 and postamble 726. To minimize power consumption, the encoding could be designed to minimize the number of pulse edges traveling through an inverter per bit of information stored. The encoding should also be designed to use larger pulse widths to make accurate reading of the pulses and their continued oscillations less sensitive to noise.

The pattern could include a high or low voltage value in each interval to represent the value of that interval. The pattern of pulses could include the duration for which each voltage value at a specific point on the loop of inverters was maintained. As an example, pulse width 723 of pulse 720 is associated with the value 33 and pulse width 727 of pulse 724 is associated with the value 74, with pulse width 727 being wider than pulse width 723. The association between values and pulse widths can be arbitrarily assigned but noise resistance can be improved if the values are assigned monotonically and in fixed steps with the readable changes in the width of the pulses.

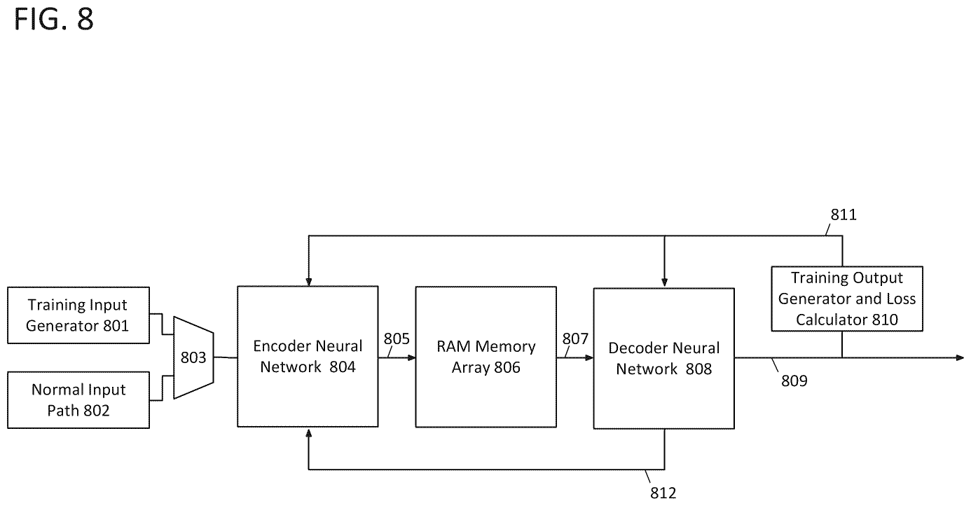

FIG. 8 illustrates a read circuit and a write circuit for a RAM memory array 806 that have been augmented with encoder neural network 804 and decoder neural network 808 in accordance with specific embodiments of the inventions disclosed herein. As can be seen in the figure, encoder neural network 804 can deliver encoded clean input values 805 to be stored in RAM memory array 806, and decoder neural network 808 can modify the noisy output values 807 into denoised outputs 809. The illustrated approach can work well with RAM arrays that store values using analog oscillation states such as the patterns or pulse widths mentioned herein. Encoder neural network 804 and decoder neural network 808 can be hardware implemented and integrated with RAM memory array 806.

The combined system can include multiplexer 803 to feed in training inputs from training data input generator 801 for the training phase of the neural network. As shown, the system can also include training output generator and loss calculator 810 with knowledge of the inputs provided by training data input generator 801. The figure also shows how the loss for neural network training 811 can be fed back to decoder neural network 808 and encoder neural network 804 during training. In specific embodiments, the loss can be fed back to decoder neural network 808 and then indirectly via gradient flow to encoder neural network 804. Gradient flow 812 for neural network training can be fed to encoder neural network 804 from decoder neural network 808. Once trained, the weights of encoder neural network 804 and decoder neural network 808 can be fixed using ROM or any form of nonvolatile memory. Alternatively, encoder neural network 804 and decoder neural network 808 can be periodically retrained in phases between operational use of the RAM to store actual normal input data. Multiplexer 803 may switch inputs from training data input generator 801 to normal input path 802. For example, multiplexer 803 may switch to normal input path 802 once the system is trained. Normal input path 802 may input data used during normal operation (e.g., not during the training of the neural network).

RAM memory array 806 can be integrated with a processor on the same substrate and integrated circuit. Alternatively, the RAM memory array 806 can be built on its own substrate but be packaged with alternative integrated circuits with processors in a single package. Alternatively, RAM memory array 806 can be stand-alone memory components on a separate integrated circuit or package. For example, RAM memory array 806 could be encapsulated in a chiplet designed to interoperate with alternative chiplets that may include other components such as processors. The processors that will utilize RAM memory array 806 can be part of a dedicated accelerator for machine intelligence applications, cryptography applications, or graphics processing applications, or can be part of a general central processing unit. The processors can be multicore processors.

In specific embodiments, RAM memory array 806 can be integrated with a processor with at least one processing core comprising computational units. The computational units can be arithmetic logic units, floating point units, or other logic. The computational units can include logic transistors that are connected together to form logic gates. The logic transistors can be FET transistors designed for rapid and efficient processing. The logic transistors can be fin-FETs, gate-all-around transistors, nanowire transistors, quantum tunnel FETs, carbon nanotube transistors, graphene and other two-dimensional material transistors, electron spin transistors, or other transistor technologies. The processor can conduct computations using a set of logic transistors where the logic transistors are any of the types of transistors mentioned above.

In specific embodiments, the inverter loops (e.g., inverter loop 100, 200, 300, 400, 500, or 600) can be formed by a set of inverter transistors. The set of inverter transistors can be the same type of transistors as the set of logic transistors. In specific embodiments, the inverter loops can form a RAM for a processor which is integrated on the same substrate as RAM memory array 806, and the set of logic transistors for the processor and the set of inverter transistors for the set of inverters can be the same type of transistors. In specific embodiments, the inverter loops can form RAM memory array 806 for a processor which is integrated on the same substrate as RAM memory array 806, and the set of logic transistors for the processor and the set of inverter transistors for the set of inverters (e.g., inverter loops) can be formed using a common process flow. In these embodiments, there may be minor additional steps conducted for either the logic transistors or the inverter transistors, but the core processing steps and device types for the two sets of transistors may be the same. The set of inverter transistors can be the minimum sizes FETs for the processing node used to form the set of logic transistors. The set of inverter transistors can be the standard sized FETs used for the set of logic transistors. These embodiments will exhibit a greater degree of integration between RAM memory array 806 and the logic as compared to current approaches and can result in better alignment and layout of RAM memory array 806 and logic on an integrated circuit. For example, blocks of RAM transistors of RAM memory array 806 could be mixed in with blocks of computational logic transistors instead of having one area of a chip reserved for memory and another area of the chip reserved for logic. Furthermore, if the inverter FETs are comparable in size to the logic FETs, then RAM memory array 806 will exhibit much greater density than current state of the art SRAM devices and that advantage will continue to increase as chip fabrication processes move towards smaller processing nodes.

Systems in accordance with this disclosure in which the RAM formed of loops of inverters (e.g., RAM memory array 806) is integrated with a processor having logic transistors can include a memory array voltage regulator that provides a memory supply voltage to the loops of inverters in the array of loops of inverters. The system can also include a supply voltage for the logic transistors of the processor. The memory supply voltage can be derived from the supply voltage for the logic transistors in that the supply voltage for the logic transistors is an input to the memory array voltage regulator. The supply voltage for the logic transistors can be greater than the memory supply voltage. For example, the supply voltage for the logic transistors can be greater than 1 volt and the memory supply voltage can be less than 500 milli-volts.

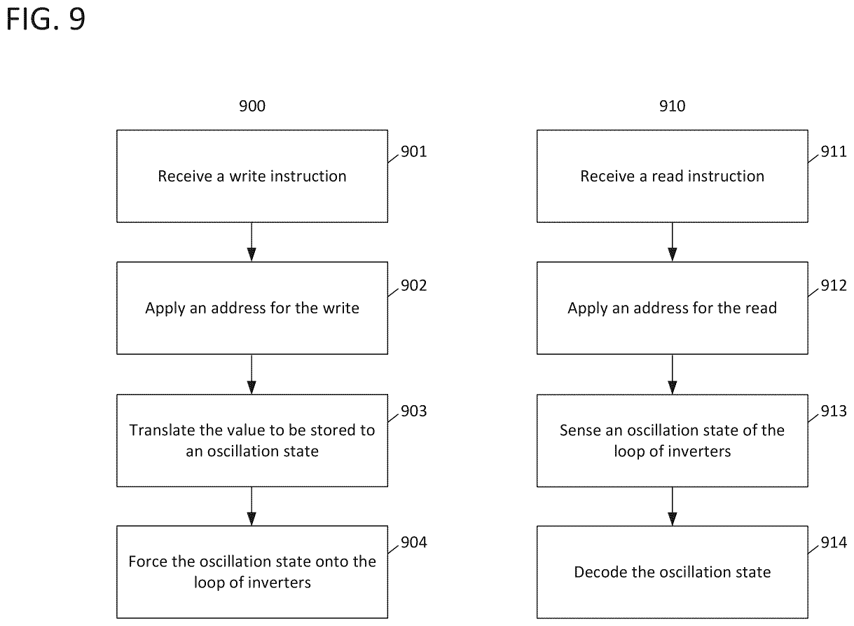

FIG. 9 illustrates an example of write method 900 and read method 910 in accordance with specific embodiments of the inventions disclosed herein. Some portions of the methods may be performed out of order, others may be skipped, others may be duplicated. Each loop of inverters may store a value associated with an oscillation state of the loop of inverters by being placed into that oscillation state by a write circuit and by having that oscillation state detected by a read circuit. As in standard memory architectures, multiple memory cells may share the same read circuit and write circuit. Loops of inverters may be independently readable and independently writable using a set of corresponding addresses.

At 901, a write instruction may be received. The write instruction may be directed to a RAM array with loops of inverters. The write instruction may be for a single bit of data or multiple bits of data. The write instruction may be for binary bit values or multibit values.

At 902, an address for the write may be applied. The loops of inverters may be independently addressed. Inherent or explicit addressing of individual memory cells may be used. The write circuit may be addressed with specific control signals to access a given loop of inverters to write a value thereto.

At 903, the one or more bit values to be stored in the memory (e.g., in one or more inverter loops) may be translated into an oscillation state, such as an oscillation state referring to a pattern of pulses. The pattern may be a number of pulses expressed by a given signal node during the loop period where the number of pulses alone stores the informational content of the pattern. The pattern may be whether or not the inverter loop oscillates. The pattern may be a sequential pattern of high and low values expressed by a given signal node where the order of the high and low values stores the informational content of the pattern. The pattern could include a high or low voltage value in each interval to represent the value of that interval. The pattern could also include multiple pulses in an interval with a counter used to count the pulses in an interval. The pattern of pulses could include the duration for which each voltage value at a specific point on the loop of inverters was maintained. The pattern may store values according to a pulse width oscillating in the loop of inverters. In specific embodiments, at least one neural network circuit can be trained to assist the write circuits to recover noisy values from the loops of inverters by modifying the manner in which the value is translated into an oscillation state.

The loop of inverters could store a value in an oscillation state defined by a pattern of pulses looping through the loop. The pattern of pulses may utilize a non-return to zero or return to zero encoding. The pattern could be any type of line encoding. The pattern may be any waveform (e.g., repeating or not repeating) that may be sustained on the loop of inverters through multiple loops. The pattern may or may not consume an entire loop period of the loop of inverters. The pattern may include break periods between intervals to assure adequate time for a read circuit to ascertain the correct value for a given interval. The pattern may include a start code. The read and write circuits may be configured to ignore portions of the loop period which are not consumed by the pattern and do not correspond to the stored value.

To minimize power consumption, the encoding may be designed to minimize the number of pulse edges traveling through an inverter per bit of information stored. The encoding may also be designed to use larger pulse widths to make accurate reading of the pulses and to make the continued oscillation of pulses less sensitive to noise. An encoding neural network can form part of the write circuit.

At 904, the oscillation state (e.g., from 903) may be forced onto the loop of inverters. The write circuit may be connected to circuits that isolate the transistors of one or more inverters (of the loop of inverters) that are connected to the signal nodes from a supply voltage or a reference voltage to force the state of the one or more inverters to output high, low, or a float state. A write circuit may be designed to set the oscillation state by forcing the pattern on the loop of inverters, for example via a control circuit. A control circuit in series with a chain of the loop of inverters may be able to force a high or low value into a signal node to an input of the next inverter in the chain. The write circuit may be configured to break the inverter loop (e.g., ring) oscillator feedback, such as by using a control circuit in series with the other inverters in the loop, or a control circuit that can pull specific inverter outputs to the reference voltage or supply voltage. The write circuit may also be configured to inject the pattern into the loop of inverters by pulling a signal node down to a reference voltage and back up to the supply voltage repeatedly in accordance with the pattern. The write circuit may also be configured to close the feedback for the loop of inverters after forcing the signal node to the final value of the pattern. In specific embodiments, the write circuit may be configured to remove its influence from the loop of inverters as soon as the oscillator state has been imparted to the loop of inverters. For example, a current source write circuit can cease injecting or sinking current from a signal node, or a voltage source write circuit can cease controlling the voltage on a signal node. In specific embodiments, the write circuit can change the configuration of the loop of inverters as soon as the oscillator state has been imparted to the loop of inverters (e.g., the number of inverters in the chain can be modified).

Prior to forcing the oscillation state, the write circuit may flush the signal nodes of the loop of inverters to a constant value, such as zero or one. Forcing the oscillation state may include breaking the feedback of any oscillation state the loop of inverters may be in (e.g., prior to receiving the write command).

The write circuit may be designed to force a signal node to a low value for the loop period plus a margin of error to make sure the loop is completely flushed, then force the signal node to a high value, and to then measure the time it takes for the altered signal to circumvent the loop and reach the signal node just prior to the signal node being forced to the high value. The write circuit may use that measurement to determine the loop period and may then send in a pulse that is a percentage of that number. Alternatively, the write circuit may be designed to flush the loop and then enter a pulse with a fixed time period where the fixed period is associated with the value that is intended to be stored in the loop of inverters.

Read method 910 may be performed, for example, to read the data that was written using write method 900. At 911, a read instruction may be received. The read instruction may be directed to a RAM array with loops of inverters.

At 912, an address for the read may be applied. The loops of inverters may be independently addressed. Inherent or explicit addressing of individual memory cells may be used. The read circuit may be addressed with specific control signals to access a given loop of inverters to read a value therefrom.

At 913, an oscillation state of the loop of inverters may be sensed (e.g., via one or more signal nodes). A read circuit could be designed to detect the oscillation state (and therefore the value that the loop of inverters stores) by determining the pattern on the loop of inverters. Sensors may be coupled with or be part of one or more read circuits that read or detect the oscillation state of the loop of inverters. In specific embodiments, multiple bits may be read based on a single oscillation state or waveform. The read circuit may include sensing circuits coupled in series with the chain of inverters.

The value stored in the inverter loop may be sensed in a variety of ways. The pattern may include break periods between intervals to assure adequate time for a read circuit to ascertain the correct value for a given interval. The read and write circuits may be configured to ignore portions of the loop period which are not consumed by the pattern and do not correspond to the stored value.

The value may be defined by the waveform that occurs when monitoring a given signal node of the loop of inverters over time (e.g., continuously). The monitoring may be split into distinct intervals. The read circuit can comprise a clock data recovery circuit. Detecting the pattern of pulses can comprise measuring a voltage on the loop of inverters according to a set of fixed time intervals using the clock data recovery circuit. Detecting the pattern of pulses can also comprise measuring a voltage on the loop of inverters according to a set of fixed time intervals using a latch and a clock circuit set to pulse according to the time intervals.

The value (e.g., bit) may be defined by the value (e.g., high or low) of that waveform at specific moments of time. For example, every 100 nanoseconds the voltage on a portion (e.g., at a signal node) of a loop of inverters could be sampled and the sampled voltage values could define the value. If the voltages are high, a bit stored at that interval in the inverter loop would be one, while if the voltages were low, a bit stored at that interval in the inverter loop would be zero.

The pattern may be a number of pulses expressed by a given signal node during the loop period where the number of pulses alone stores the informational content of the pattern. The pattern may be whether or not the inverter loop oscillates. The pattern could include a high or low voltage value in each interval to represent the value of that interval. A sense amplifier may sense one of the signal nodes for a duration of time corresponding to the time it takes a pulse to go through the loop (e.g., loop period).

Read circuits may include sensing circuits with high impedance contacts to the signal nodes to the chain for purposes of reading the inverter chain. For example, a gate of a FET in a sensing circuit such as the clock input of a flip flop (e.g., toggle flip flop) or a counter circuit could be coupled to a signal node to determine if a pulse has moved through a signal node. The read circuit may include an oscillator, and the oscillator may be coupled to the counter circuit. The oscillator may have a period that is substantially shorter than the loop period of the loop of inverters. In combination, the oscillator and counter circuit may measure the duration of a pulse in a number of periods of the oscillator counted by the counter circuit while the pulse had a specific value. The counter circuit could reset upon detecting an opposite binary value from the specific value, or another specific value indicative of the absence of a pulse. The read and write circuits may alternatively or in combination be connected to circuits that isolate the transistors of the inverter that are connected to the signal nodes from a supply voltage or a reference voltage to force the state of an inverter output high, low, or to a float state.

The pattern may be a sequential pattern of high and low values expressed by a given signal node where the order of the high and low values stored the informational content of the pattern. The pattern could also include multiple pulses in an interval with a counter used to count the pulses in an interval. A sense amplifier and a counter may work in combination to sense the oscillation state. If the pattern is a simple number of pulses and the order of high and low values is not an aspect that distinguishes the pattern from other oscillation states that represent alternative values, the read circuit may be (or include) a simple counter circuit that counts the number of pulses.

The pattern of pulses could include the duration for which each voltage value at a specific point on the loop of inverters was maintained. The pattern may store values according to a pulse width oscillating in the loop of inverters. A sense amplifier and a timer may work in combination to sense the oscillation state.

In specific embodiments, the value may be defined by reading multiple points on the loop of inverters simultaneously. For example, sensing the voltages at different signal nodes may increase the read speed of the circuit. In specific embodiments, more than one (e.g., all) of the signal nodes of a loop of inverters may be connected to a high impedance node capable of determining the voltage of the node at a given time and multiple portions of the waveform on the loop of inverters may be read at the same time. Read circuits in the case of reading off multiple signal nodes simultaneously, can involve multiple copies of such circuits with inputs connected to the associated signal node.

At 914, the oscillation state of the loop of inverters (e.g., sensed at 913) may be decoded into one or more bits. In specific embodiments, at least one neural network circuit can be trained to assist the read circuits or the write circuits to recover noisy values from the loops of inverters. For example, a decoding neural network can form part of the read circuit.

In specific embodiments, loops of inverters may be written to and read from in various ways, allowing flexibility and reliability in memory storage, while the hardware (e.g., loops of inverters) that stores the memory is relatively small and may be integrated into computational units. In specific embodiments, loops of inverters may have low power consumption and may store values efficiently.

At least one processor in accordance with this disclosure can include at least one non-transitory computer readable media. The at least one processor could comprise at least one computational node in a network of computational nodes. The media could include cache memories on the processor. The media can also include shared memories that are not associated with a unique computational node. The media could be a shared memory, could be a shared random-access memory, and could be, for example, a double data rate (DDR) DRAM. The shared memory can be accessed by multiple channels. The non-transitory computer readable media can store data required for the execution of any of the methods disclosed herein, the instruction data disclosed herein, and/or the operand data disclosed herein. The computer readable media can also store instructions which, when executed by the system, cause the system to execute the methods disclosed herein. The concept of executing instructions is used herein to describe the operation of a device conducting any logic or data movement operation, even if the “instructions” are specified entirely in hardware (e.g., an AND gate executes an “and” instruction). The term is not meant to impute the ability to be programmable to a device.

While the specification has been described in detail with respect to specific embodiments of the invention, it will be appreciated that those skilled in the art, upon attaining an understanding of the foregoing, may readily conceive of alterations to, variations of, and equivalents to these embodiments. Any of the method steps discussed above can be conducted by a processor operating with a computer-readable non-transitory medium storing instructions for those method steps. The computer-readable medium may be memory within a personal user device or a network accessible memory. Although examples in the disclosure were generally directed to bistable inverters, the same approaches could be utilized with inverters having more complex input and output relationships such as multibit inverters with multiple input states matched to multiple output states. A means for writing values to loops of inverters independently using a set of corresponding addresses can be any of the write circuits disclosed herein combined with control circuitry that can apply the value to be stored to the write circuit and activated a write circuit associated with a target loop of inverters when supplied with a physical signal representing the address associated with that target loop of inverters. A means for reading values from loops of inverters independently using a set of corresponding addresses can be any of the read circuits disclosed herein combined with control circuitry that can activate a read circuit associated with a target loop of inverters when supplied with a physical signal representing the address associated with that target loop of inverters. These and other modifications and variations to the present invention may be practiced by those skilled in the art, without departing from the scope of the present invention, which is more particularly set forth in the appended claims.

What is claimed is:

1. A random access memory comprising:
a set of loops of inverters, wherein the loops of inverters in the set of loops of inverters are addressable using a set of corresponding addresses;
a write circuit configured to write a value to a first loop of inverters when provided with a corresponding address for the first loop of inverters, wherein the first loop of inverters is in the set of loops of inverters and the corresponding address is in the set of corresponding addresses; and
a read circuit configured to read the value from the first loop of inverters when provided with the corresponding address.

2. The random access memory of claim 1, wherein:
the random access memory is integrated with a processor;
the processor conducts computations using a set of logic transistors;
the loops of inverters are formed by a set of inverter transistors; and
the set of logic transistors and the set of inverter transistors are formed using a common process flow.

3. The random access memory of claim 1, wherein:
the random access memory is integrated with a processor;
the processor conducts computations using a set of logic transistors;
the loops of inverters are formed by a set of inverter transistors; and
the set of logic transistors and the set of inverter transistors are field effect transistors.

4. The random access memory of claim 3, wherein:
the inverters in the loops of inverters each comprise two complementary field effect transistors.

5. The random access memory of claim 1, wherein:
the loops of inverters in the set of loops of inverters each consist of an odd number of inverters.

6. The random access memory of claim 1, wherein:
the write circuit is configured to write the value to the first loop of inverters by forcing the first loop of inverters into an oscillation state; and
the read circuit is configured to read the value from the first loop of inverters by detecting the oscillation state of the first loop of inverters.

7. The random access memory of claim 1, wherein:
the read circuit is configured to read the value from the first loop of inverters by detecting a pattern of pulses on the first loop of inverters.

8. The random access memory of claim 1, wherein:
the read circuit is configured to read the value from the first loop of inverters by measuring a pulse width of a pulse from the loop of inverters.

9. The random access memory of claim 8, wherein the read circuit comprises:
a toggle flip flop with a clock input;
wherein the clock input is coupled to the first loop of inverters.

10. The random access memory of claim 9, wherein the read circuit comprises:
a clock data recovery circuit;
wherein reading the value from the first loop of inverters comprises measuring a voltage on the loop of inverters at a set of fixed time intervals.

11. The random access memory of claim 10, wherein the read circuit comprises:
an oscillator; and
a counter circuit;
wherein the counter circuit is coupled to the oscillator and the first loop of inverters, and the oscillator has a period that is substantially shorter than a period of the first loop of inverters.

12. The random access memory of claim 1, further comprising:
a memory array voltage regulator that provides a memory supply voltage to the loops of inverters in the set of loops of inverters;
wherein the random access memory is integrated with a processor having logic transistors, and a supply voltage for the logic transistors of the processor is greater than the memory supply voltage.

13. The random access memory of claim 1, further comprising:
a memory array voltage regulator that provides a memory supply voltage to the loops of inverters in the set of loops of inverters; and
a pair of transistors that form part of an inverter in the loops of inverters, wherein the pair of transistors have a pair of threshold voltage;
wherein the memory supply voltage is equal to or less than a sum of the pair of threshold voltages.

14. The random access memory of claim 1, further comprising:
an encoding neural network that forms part of the write circuit; and
a decoding neural network that forms part of the read circuit.

15. A random access memory comprising:
an array of loops of inverters wherein the loops of inverters in the array of loops of inverters are independently readable and independently writable using a set of corresponding addresses;
at least one write circuit configured to set an oscillation state of the loops of inverters independently using the set of corresponding addresses; and
at least one read circuit configured to sense the oscillation state of the loops of inverters independently using the set of corresponding addresses.

16. The random access memory of claim 15, wherein:
the random access memory is integrated with a processor;
the processor conducts computations using a set of logic transistors;
the loops of inverters are formed by a set of inverter transistors; and
the set of logic transistors and the set of inverter transistors are formed using a common process flow.

17. The random access memory of claim 15, wherein:
the random access memory is integrated with a processor;
the processor conducts computations using a set of logic transistors;
the loops of inverters are formed by a set of inverter transistors; and
the set of logic transistors and the set of inverter transistors are field effect transistors.

18. The random access memory of claim 17, wherein:
the inverters in the loops of inverters each comprise two complementary field effect transistors.

19. The random access memory of claim 15, wherein:
the loops of inverters in the array of loops of inverters each consist of an odd number of inverters.

20. A random access memory comprising:
an array of loops of inverters wherein the loops of inverters in the array of loops of inverters are independently readable and independently writable using a set of corresponding addresses;
a means for writing values to the loops of inverters independently using the set of corresponding addresses; and
a means for reading the values from the loops of inverters independently using the set of corresponding addresses.
